(19) United States
(12) Patent Application Publication
(10) Pub. No.: US 2003/0216048 A1
(43) Pub. Date: Nov. 20, 2003

(54) Method for poly tip shape fabrication and tip shape application

(75) Inventors: Shian-Jyh Lin, Chiayi Hsien (TW); Chung-Lin Huang, Taichung (TW); Ming-Yuan Huang, Yunlin (TW); Chao Sung Lai, Taoyuan (TW); Kuo-Chung Chen, Sanchung City (TW)

Correspondence Address: Richard P. Berg, Esq., c/o LADAS & PARRY, Suite 2100, 5670 Wilshire Boulevard, Los Angeles, CA, 90036-5679, US

(73) Assignee: NANYA TECHNOLOGY CORPORATION

(21) Appl. No.: 10/409,905

(22) Filed: Apr. 8, 2003

(30) Foreign Application Priority Data
May 14, 2002 (TW) 91110048

(51) Int. Cl. H01L 21/311

(52) U.S. Cl. 438/694

(57) ABSTRACT

A method for fabricating a floating gate. A semiconductor substrate is provided, on which an insulating layer, conductive layer, and patterned hard mask layer are sequentially formed. The hard mask layer and the conductive layer are sequentially etched to form a trench. The exposed conductive layer is oxidized to form an oxide layer. The hard mask layer is removed. The conductive layer where not covered by the oxide layer is removed using the oxide layer as a mask.

### BACKGROUND OF THE INVENTION

1. Field of the Invention

The invention relates to a tip shape semiconductor process, and more particularly to a floating gate fabrication process to form a floating gate with a tip.

2. Description of the Related Art

Memory devices for non-volatile storage of information are currently in widespread use, in a myriad of applications. A few examples of non-volatile semiconductor memory include read only memory (ROM), programmable read only memory (PROM), erasable programmable read only memory (EPROM), electrically erasable programmable read only memory (EEPROM) and flash EEPROM.

An advantage of EPROM is that it is electrically programmed, but for erasing, EPROM requires exposure to ultraviolet (UV) light.

In many circuit designs it is desirable to have a non-volatile memory device that can be erased and reprogrammed in-circuit, without the need to remove the device.

EEPROM devices have the advantage of electrical programming and erasing, achieved by charging and discharging actions controlled by the control gate. The actions also affect the conductivity of the channel between source and drain.

One of the advantages of flash memory is its capacity for block-by-block memory erasure. Furthermore, memory erasure is fast, and normally takes just 1 to 2 seconds for the complete removal of a whole block of memory.

FIGS. 1a to 1c are cross-sections of the conventional method for fabricating a floating gate of a flash memory.

In FIG. 1a, a silicon substrate 101 is provided, with a gate oxide layer 102, doped polysilicon layer 103, and nitride layer 104 having an opening 105 are sequentially formed thereon.

In FIG. 1b, the doped polysilicon layer 105, where exposed by the opening 105, is oxidized to form an oxide layer 106, with an edge thereof forming a bird's beak shape.

In FIG. 1c, the nitride layer 104 is removed. The doped polysilicon layer 103 is anisotropic etched to form a floating gate 103a using the oxide layer 106 as an etching mask.

When the edge of the floating gate is a tip, the electric field is easily concentrated, and the point is easily discharged. If the point discharge is increased, effects of erasure will be increased.

### SUMMARY OF THE INVENTION

The present invention is directed to a floating gate with multiple tips and a method for fabricating the floating gate.

Accordingly, the present invention provides a method for fabricating a floating gate. A semiconductor substrate is provided, with an insulating layer, conductive layer, and patterned hard mask layer sequentially formed thereon. The patterned hard mask layer and the conductive layer are sequentially etched to form a trench. The exposed conductive layer is oxidized to form an oxide layer. The patterned hard mask layer is removed. The conductive layer is etched using the oxide layer as a mask.

Accordingly, the present invention provides another method for fabricating a floating gate having a tip. A semiconductor substrate is provided, with an oxide layer, polysilicon layer, and nitride layer sequentially formed thereon. The nitride layer is patterned. The nitride layer and the polysilicon layer are sequentially etched to form a trench. The polysilicon, where the surface is exposed, is thermally oxidized to form a bird's beak shape edge polysilicon oxide layer. The nitride layer is removed. The polysilicon layer is anisotropically etched using the polysilicon oxide layer as a mask.

### BRIEF DESCRIPTION OF THE DRAWINGS

For a better understanding of the present invention, reference is made to a detailed description to be read in conjunction with the accompanying drawings, in which:

FIGS. 1a to 1c are cross-sections of the conventional method for fabricating a floating gate of a flash memory;

FIGS. 2a to 2h are cross-sections of the method for fabricating a floating gate of a flash memory of the present invention.

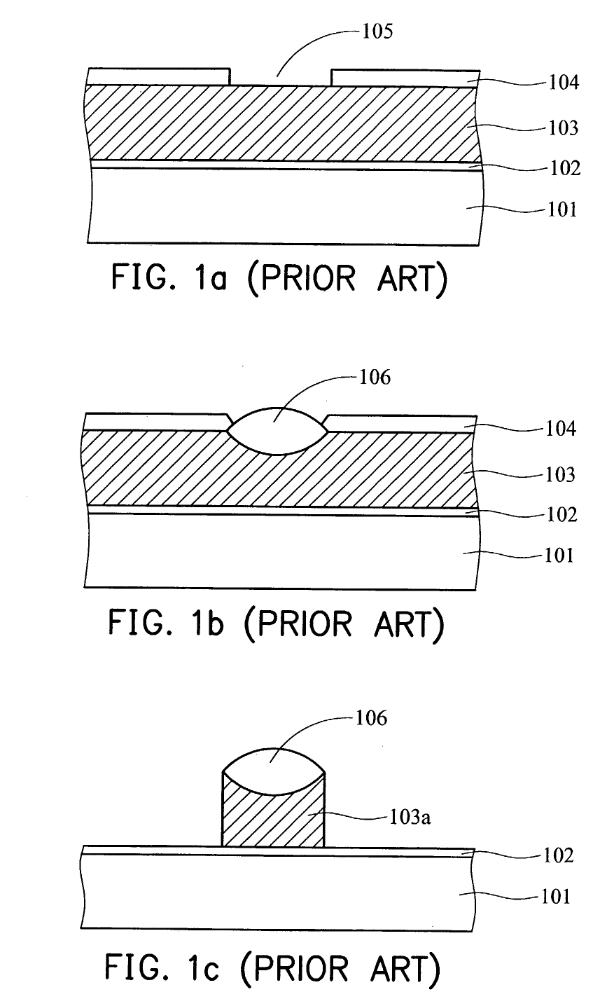

### DETAILED DESCRIPTION OF THE INVENTION

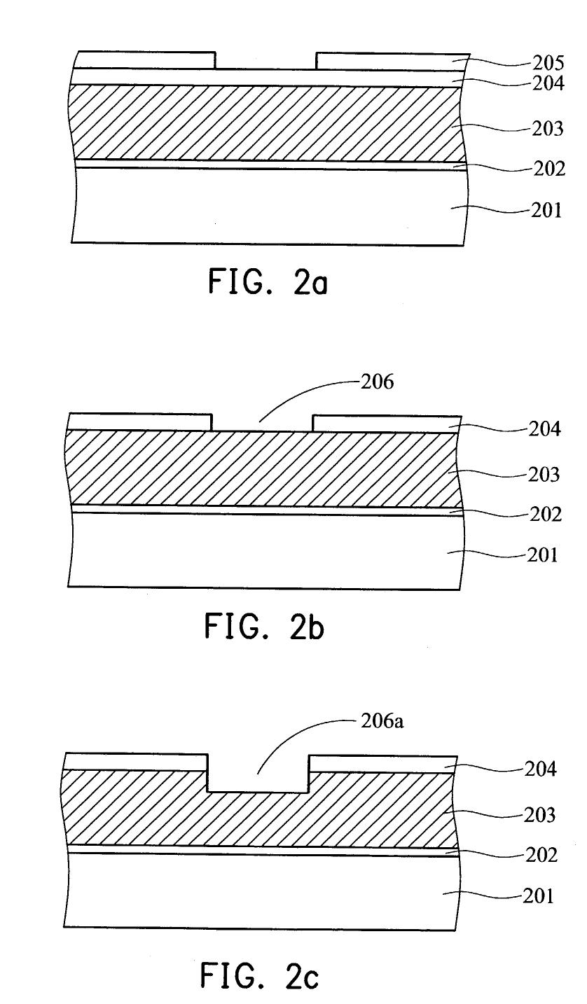

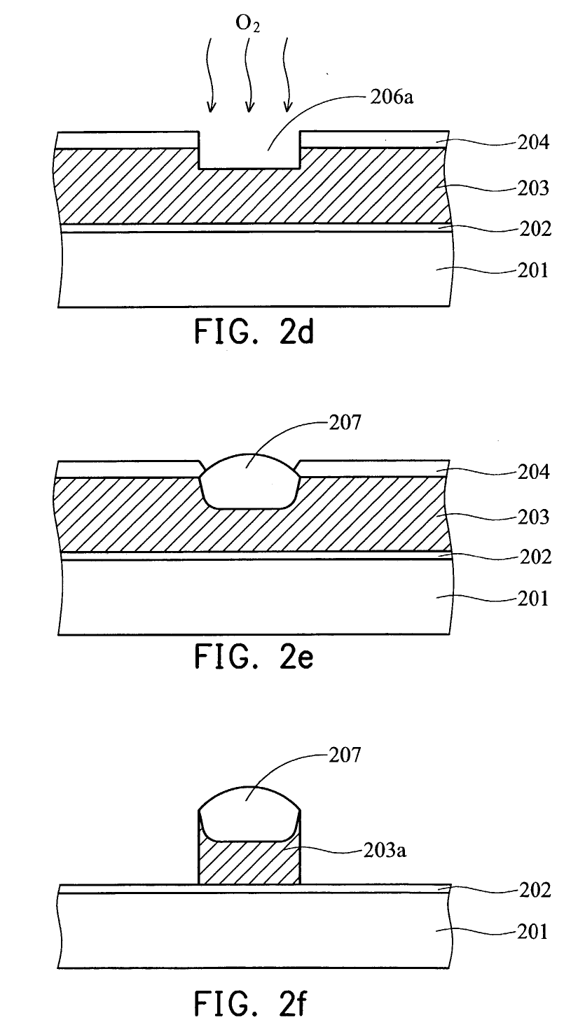

FIGS. 2a to 2h are cross-sections of the method for fabricating a floating gate of a flash memory of the present invention.

In FIG. 2a, a semiconductor substrate 201 is provided, with an insulating layer 202, a conducting layer 203, a hard mask layer 204, and a photoresist layer 205 with an opening, sequentially formed thereon. The materials underlying the hard mask layer 204 are protected from oxidization. The insulating layer 202 comprises a pad oxide layer. The conducting layer 203 comprises a metal layer, such as Al, Cu, W, WSi, MO, and Fe, and a polysilicon layer. The hard mask layer 204 comprises a nitride layer to protect the poly or metal from oxidization.

In FIG. 2b, the hard mask layer 204 is anisotropically etched to form a trench 206 using the photoresist layer 205 as a mask.

In FIG. 2c, the conducting layer is overetched to form a trench 206a after forming the trench 206, and the photoresist layer 205 is removed. The position of the trench 206a is the position for forming a floating gate. The depth of trench 206a in the conducting layer 203 is determined so that the oxide layer formed by follow-up oxidation does not contact the insulating layer 202.

In this case, the thickness of the hard mask layer 204 is about 200 Å to 1500 Å, the thickness of the conducting layer 203 is about 500 Å to 50 Å, and the depth of the trench 206a in the conducting layer 203 is about 100 Å to 1500 Å.

In FIG. 2d, the surface of the conducting layer 203 where exposed by the trench 206a is partially thermally oxidized to form an oxide layer 207, such as oxide polysilicon layer. The hard mask layer 204 protects the underlying conductor layer 203 from oxidation.

In FIG. 2e, the conducting layer 203 where exposed by the trench 206 is oxidized to form an oxide layer 207 with an edge thereof bird's beak shaped. The oxidizing rate of the conducting layer 203 of the bottom corner at the trench 206 is faster, so the oxidized conducting layer 203 of the bottom corner at the trench 206 is deeper.

In FIG. 2f, after the hard mask layer is removed, the conducting layer 203 is anisotropically etched to form a conducting layer 203a of a floating gate using the oxide layer 207 as a mask. The edge of the conducting layer 203a of the floating gate in the present invention is tip-shaped, and the edge of the floating gate is sharper than the conventional floating gate because of the conducting layer 203 of the bottom corner of the trench 206a oxidizing deeper.

Concentrated electric field occurs easily in the tip, easily discharging it. The effect of point discharge is increased by the floating gate s tip in the present invention. Thus, the data erasing effect of the flash memory having the floating gate with tip is increased.

The conventional floating gate in a Forward Tunneling Voltage (FTG) test sees about 7 to 8.5V, and the voltage of the present invention is about 6.5 to 7.5V. The floating gate is more easily erased when the forward tunneling voltage is lower. In other words, the erasing rate of the floating gate with tip of the present invention is higher than the conventional floating gate.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a floating gate, comprising:
providing a semiconductor substrate;
sequentially forming an insulating layer, a conductive layer, and a patterned hard mask layer on the semiconductor substrate;
sequentially etching the patterned hard mask layer and the conductive layer to form a trench;
oxidizing the exposed conductive layer to form an oxide layer;
removing the patterned hard mask layer; and
removing the conductive layer using the oxide layer as a mask.

2. The method for fabricating a floating gate as claimed in claim 1, wherein the insulating layer comprises a pad oxide layer.

3. The method for fabricating a floating gate as claimed in claim 1, wherein the conductive layer comprises a polysilicon layer.

4. The method for fabricating a floating gate as claimed in claim 1, wherein the conductive layer comprises a metal layer.

5. The method for fabricating a floating gate as claimed in claim 4, wherein the metal layer comprises Al, Cu, W, WSi, MO, and Fe.

6. The method for fabricating a floating gate as claimed in claim 1, wherein the patterned hard mask layer is a nitride layer.

7. The method for fabricating a floating gate as claimed in claim 1, wherein the oxidization method is thermal oxidation.

8. The method for fabricating a floating gate as claimed in claim 1, wherein the oxide layer is a silicon oxide layer.

9. The method for fabricating a floating gate as claimed in claim 8, wherein an edge of the silicon oxide layer has a Bird's beak shape.

10. The method for fabricating a floating gate as claimed in claim 1, wherein the method of etching is anisotropic etching.

11. A method for fabricating a floating gate having a tip, comprising:
providing a semiconductor substrate;
sequentially forming an oxide layer, a conducting layer, and a nitride layer thereon;
patterning the nitride layer;
sequentially etching the nitride layer and the conducting layer to form a trench;
thermally oxidizing the exposed conducting layer to form a Bird's beak shape edge thereon;
removing the nitride layer; and
anisotropically etching the conducting layer by the conducting oxide layer using the Bird's beak shape edge as a mask.

12. The method for fabricating a floating gate as claimed in claim 11, wherein the conductive layer comprises a polysilicon layer.

13. The method for fabricating a floating gate as claimed in claim 11, wherein the conductive layer comprises a metal layer.

14. The method for fabricating a floating gate as claimed in claim 13, wherein the metal layer comprises Al, Cu, W, WSi, MO, and Fe.

15. The method for fabricating a floating gate as claimed in claim 11, wherein the thickness of the conducting layer is about 500 Å to 50 Å.

16. The method for fabricating a floating gate as claimed in claim 11, wherein the depth of the trench is about 100 Å to 1500 Å.
